(19) United States
(12) Patent Application Publication
(10) Pub. No.: US 2024/0318343 A1
(43) Pub. Date: Sep. 26, 2024

(54) SUBSTRATE LIQUID PROCESSING APPARATUS AND SUBSTRATE LIQUID PROCESSING METHOD

(71) Applicant: Tokyo Electron Limited, Tokyo (JP)

(72) Inventors: Kazuyuki Goto, Kikuchi-gun, Kumamoto (JP); Masatoshi Shiraishi, Kikuchi-gun, Kumamoto (JP); Masato Hamada, Kikuchi-gun, Kumamoto (JP)

(21) Appl. No.: 18/578,448

(22) PCT Filed: Jun. 29, 2022
(86) PCT No.: PCT/JP2022/025947

§ 371 Date: Jan. 11, 2024

(30) Foreign Application Priority Data
Jul. 12, 2021 (JP) 2021-115292

(51) Int. Cl. C25D 7/12; C25D 5/54; C25D 17/00; C25D 21/12; H01L 21/288

(52) U.S. Cl. CPC C25D 7/123; C25D 5/54; C25D 17/001; C25D 21/12; H01L 21/288

(57) ABSTRACT

A controller outputs a control signal to control a plating liquid supply and a power applying device to perform a first electrolytic plating processing by applying power to a processing surface in a state that a plating liquid is in contact with a first facing range, which is a partial range of an electrode facing surface, and the controller also outputs, after the first electrolytic plating processing is performed, a control signal to control the plating liquid supply and the power applying device to perform a second electrolytic plating processing by applying the power to the processing surface in a state that the plating liquid is in contact with a second facing range of the electrode facing surface, the second facing range being wider than the first facing range.

### TECHNICAL FIELD

The various aspects and embodiments described herein pertain generally to a substrate liquid processing apparatus and a substrate liquid processing method.

### BACKGROUND

Electrolytic plating (electroplating) is used to bury a metal wiring in a fine recess (trench, etc.) of a semiconductor substrate. Patent Document 1 discloses a single-wafer type substrate processing apparatus for manufacturing a copper circuit board by using the electrolytic plating.

### PRIOR ART DOCUMENT

Patent Document 1: Japanese Patent Laid-open Publication No. 2005-133160

### DISCLOSURE OF THE INVENTION

In an electrolytic plating processing, a plating metal is deposited on a seed layer of a substrate (wafer) by applying electricity to the substrate (wafer). More specifically, by applying the electricity to the entire substrate through an electrode connected to an outer peripheral portion of the substrate, the plating metal is deposited on the entire processing surface of the substrate.

When applying the electricity to the substrate in this way, a voltage drop occurs in the substrate due to electrical resistance of the seed layer. The degree of this voltage drop increases with an increase of a distance from the electrode connection portion (i.e., the outer peripheral portion of the substrate). For this reason, as compared to a plating speed at the outer peripheral portion of the substrate, the plating speed at a central portion of the substrate becomes slower, causing the film thickness of the plating metal ultimately deposited on the substrate to be largely different between the outer peripheral portion of the substrate and the central portion of the substrate.

Meanwhile, with a recent trend of further miniaturization of a substrate wiring, there is a demand for an even thinner seed layer. As the seed layer becomes thinner, the electrical resistance of the seed layer increases, which in turn results in an increase of the degree of the voltage drop that occurs in the substrate during the electrolytic plating processing. For this reason, as the seed layer becomes thinner, uniformizing the film thickness of the plating metal deposited on the substrate is further hindered.

Exemplary embodiments provide a technique advantageous to uniformize the film thickness of the plating metal deposited on the substrate in the electrolytic plating.

In an exemplary embodiment, a substrate liquid processing apparatus includes a substrate holder configured to hold a substrate rotatably; a first electrode configured to be brought into contact with the substrate held by the substrate holder; a second electrode having an electrode facing surface, the electrode facing surface being configured to be disposed at a position facing a processing surface of the substrate held by the substrate holder; a seal member configured to surround the processing surface; a plating liquid supply configured to supply a plating liquid onto the processing surface of the substrate held by the substrate holder; a power applying device configured to apply a power to the processing surface of the substrate held by the substrate holder via the first electrode and the second electrode; and a controller. The controller outputs a control signal to control the plating liquid supply and the power applying device to perform a first electrolytic plating processing by applying the power to the processing surface in a state that the plating liquid is in contact with a first facing range, which is a partial range of the electrode facing surface, and the controller also outputs, after the first electrolytic plating processing is performed, a control signal to control the plating liquid supply and the power applying device to perform a second electrolytic plating processing by applying the power to the processing surface in a state that the plating liquid is in contact with a second facing range of the electrode facing surface, the second facing range being wider than the first facing range.

The technique according to the exemplary embodiment is advantageous to uniformize the film thickness of the plating metal deposited on the substrate in the electrolytic plating.

### BRIEF DESCRIPTION OF THE DRAWINGS

FIG. 1 is a diagram illustrating an outline of an example of a processing system.

FIG. 2 is a diagram illustrating an example of a processing device.

FIG. 3 presents an enlarged plan view of a part of a second electrode, illustrating a layout example of a plurality of power application terminals.

FIG. 4 is a diagram illustrating an example of a processing device according to a first exemplary embodiment.

FIG. 5 is a diagram illustrating another example of the processing device according to the first exemplary embodiment.

FIG. 6A is a diagram illustrating an example of a plating method according to the first exemplary embodiment.

FIG. 6B is a diagram illustrating the example of the plating method according to the first exemplary embodiment.

FIG. 6C is a diagram illustrating the example of the plating method according to the first exemplary embodiment.

FIG. 6D is a diagram illustrating the example of the plating method according to the first exemplary embodiment.

FIG. 6E is a diagram illustrating the example of the plating method according to the first exemplary embodiment.

FIG. 6F is a diagram illustrating the example of the plating method according to the first exemplary embodiment.

FIG. 6G is a diagram illustrating the example of the plating method according to the first exemplary embodiment.

FIG. 6H is a diagram illustrating the example of the plating method according to the first exemplary embodiment.

FIG. 6I is a diagram illustrating the example of the plating method according to the first exemplary embodiment.

FIG. 7A is a diagram illustrating an example of a processing device according to a second exemplary embodiment.

FIG. 7B is a diagram illustrating an example of a planar state of a substrate, showing how a plating liquid diffuses on the substrate in the processing device shown in FIG. 7A.

FIG. 8 is a diagram illustrating another example of the processing device according to the second exemplary embodiment.

FIG. 9 is a diagram illustrating still another example of the processing device according to the second exemplary embodiment.

FIG. 10A is a plan view illustrating an example of a second electrode.

FIG. 10B is an enlarged view illustrating an example of an irregularity pattern shown in FIG. 10A.

FIG. 11A is a diagram illustrating a first example of a plating method according to the second exemplary embodiment.

FIG. 11B is a diagram illustrating the first example of the plating method according to the second exemplary embodiment.

FIG. 11C is a diagram illustrating the first example of the plating method according to the second exemplary embodiment.

FIG. 11D is a diagram illustrating the first example of the plating method according to the second exemplary embodiment.

FIG. 11E is a diagram illustrating the first example of the plating method according to the second exemplary embodiment.

FIG. 11F is a diagram illustrating the first example of the plating method according to the second exemplary embodiment.

FIG. 11G is a diagram illustrating the first example of the plating method according to the second exemplary embodiment.

FIG. 11H is a diagram illustrating the first example of the plating method according to the second exemplary embodiment.

FIG. 11I is a diagram illustrating the first example of the plating method according to the second exemplary embodiment.

FIG. 12A is a diagram illustrating a second example of the plating method according to the second exemplary embodiment.

FIG. 12B is a diagram illustrating the second example of the plating method according to the second exemplary embodiment.

FIG. 12C is a diagram illustrating the second example of the plating method according to the second exemplary embodiment.

FIG. 12D is a diagram illustrating the second example of the plating method according to the second exemplary embodiment.

FIG. 12E is a diagram illustrating the second example of the plating method according to the second exemplary embodiment.

FIG. 12F is a diagram illustrating the second example of the plating method according to the second exemplary embodiment.

FIG. 12G is a diagram illustrating the second example of the plating method according to the second exemplary embodiment.

FIG. 12H is a diagram illustrating the second example of the plating method according to the second exemplary embodiment.

FIG. 12I is a diagram illustrating the second example of the plating method according to the second exemplary embodiment.

FIG. 13A is a diagram illustrating a third example of a plating method according to a third exemplary embodiment.

FIG. 13B is a diagram illustrating the third example of the plating method according to the third exemplary embodiment.

FIG. 13C is a diagram illustrating the third example of the plating method according to the third exemplary embodiment.

FIG. 13D is a diagram illustrating the third example of the plating method according to the third exemplary embodiment.

FIG. 13E is a diagram illustrating the third example of the plating method according to the third exemplary embodiment.

FIG. 13F is a diagram illustrating the third example of the plating method according to the third exemplary embodiment.

FIG. 13G is a diagram illustrating the third example of the plating method according to the third exemplary embodiment.

FIG. 13H is a diagram illustrating the third example of the plating method according to the third exemplary embodiment.

FIG. 13I is a diagram illustrating the third example of the plating method according to the third exemplary embodiment.

FIG. 14A is a plan view illustrating an electrode facing surface of a second electrode according to a first modification example.

FIG. 14B is a diagram illustrating a processing device according to the first modification example.

### DETAILED DESCRIPTION

An exemplary embodiment of the present disclosure will be described with reference to the accompanying drawings.

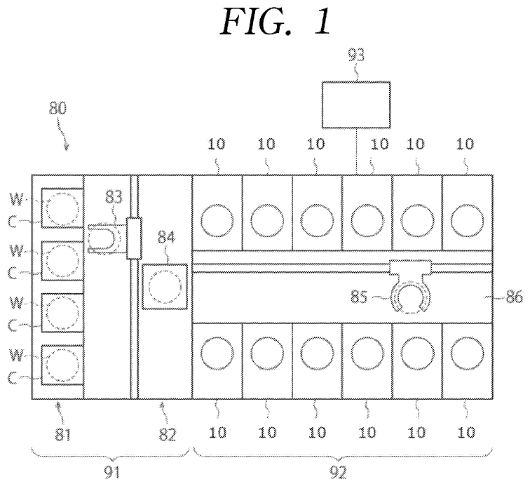

FIG. 1 is a diagram schematically illustrating an example of a processing system 80. The processing system 80 shown in FIG. 1 has a carry-in/out station 91 and a processing station 92. The carry-in/out station 91 includes a placement section 81 equipped with a plurality of carriers C, and a transfer section 82 equipped with a first transfer mechanism 83 and a delivery device 84. Each carrier C accommodates therein a plurality of substrates W horizontally. The processing station 92 is provided with a plurality of processing devices 10 installed on both sides of a transfer path 86 and a second transfer mechanism 85 configured to be moved back and forth along the transfer path 86.

A substrate W is taken out from the carrier C and loaded in the delivery device 84 by the first transfer mechanism 83, and taken out from the delivery device 84 by the second transfer mechanism 85. Then, the substrate W is carried into the corresponding processing device 10 by the second transfer mechanism 85 to be subjected to various processings in the corresponding processing device 10. Afterwards, the substrate W is taken out from the corresponding processing device 10 and loaded in the delivery device 84 by the second transfer mechanism 85, and then returned back into the carrier C in the placement section 81 by the first transfer mechanism 83.

The processing system 80 is equipped with a controller 93. The controller 93 is implemented by, for example, a computer, and includes an operation processor and a storage. The storage of the controller 93 stores therein a program and data for various processings performed in the processing system 80. The operation processor of the controller 93 appropriately reads and executes the program stored in the storage, thus controlling the various components of the processing system 80 to perform the various processings.

The program and the data stored in the storage of the controller 93 may have been recorded on a computer-readable recording medium, and may be installed from the recording medium into the storage. The computer-readable recording medium may be, by way of non-limiting example, a hard disk (HD), a flexible disk (FD), a compact disk (CD), a magnet optical disk (MO), a memory card, or the like.

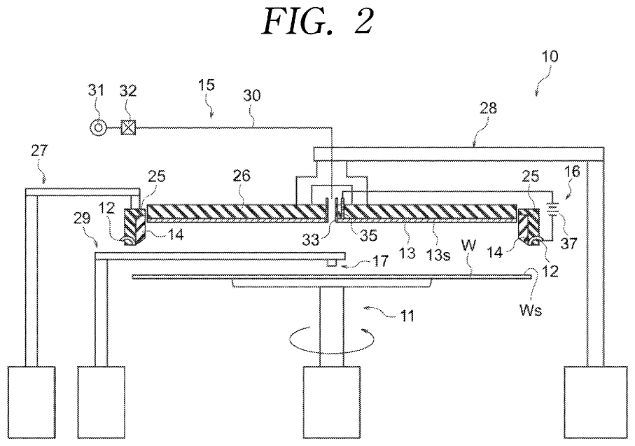

FIG. 2 is a diagram illustrating an example of the processing device 10.

The processing device 10 is equipped with a substrate holder 11, a first electrode 12, a second electrode 13, a seal member 14, a plating liquid supply 15, a power applying device 16, and a processing liquid supply 17.

The substrate holder 11 is configured to hold the substrate W rotatably under the control of the controller 93 (see FIG. 1). The substrate holder 11 receives the substrate W from the second transfer mechanism 85 (see FIG. 1) and holds it, and then hands the substrate W over to the second transfer mechanism 85 after all the processings in the processing device 10 are completed.

The way the substrate W is held by the substrate holder 11 is not particularly limited. Typically, a rear surface (particularly a central portion thereof) of the substrate W is attracted to the substrate holder 11, so that the substrate W is held by the substrate holder 11. In the state that the substrate W is held by the substrate holder 11, a processing surface Ws, which is formed of a top surface of the substrate W, extends in a horizontal direction.

In the present example, the substrate holder 11 holds the substrate W without rotating it while a plating processing to be described later is being performed. However, the substrate holder 11 may rotate the substrate W. Further, while another processing (for example, a cleaning processing, a rinsing processing, or a drying processing) is being performed on the substrate W, the substrate holder 11 may or may not rotate the substrate W.

The first electrode (cathode) 12 is configured to be brought into contact with the substrate W held by the substrate holder 11. The first electrode 12 shown in FIG. 2 is supported by a first electrode support 25, and is located at an outer side than the seal member 14 with respect to the substrate W.

The first electrode support 25 is movably supported by a first electrode mover 27. The first electrode mover 27 is configured to move the first electrode support 25 under the control of the controller 93, thereby allowing the first electrode 12 to be placed at a position (retreat position) away from the substrate W and a position (processing position) where the first electrode 12 is in contact with an outer peripheral portion (particularly, a top surface) of the substrate W. A moving direction of the first electrode 12 is not particularly limited, and it may be moved in a height direction (up-and-down direction in FIG. 2) or in a horizontal direction.

The second electrode (positive electrode) 13 has an electrode facing surface 13s. The electrode facing surface 13s is disposed at a position where it faces the processing surface Ws of the substrate W held by the substrate holder 11 during the plating processing.

For the convenience of illustration, FIG. 2 shows the second electrode 13 having a flat plate shape, and the electrode facing surface 13s is shown to extend parallel to the horizontal direction. As will be described later, however, the second electrode 13 may have a shape other than the flat plate shape. Additionally, the electrode facing surface 13s may extend non-parallel to the horizontal direction.

The second electrode 13 is supported by a second electrode support 26. The second electrode support 26 is movably supported by a second electrode mover 28. The second electrode mover 28 is configured to move the second electrode support 26 under the control of the controller 93, thus allowing the electrode facing surface 13s of the second electrode 13 to be placed at a position (retreat position) away from the processing surface Ws of the substrate W and a position (processing position) close to the processing surface Ws. A moving direction of the second electrode 13 is not particularly limited, and it may be moved in the height direction or in the horizontal direction.

The second electrode mover 28 may be configured to rotate the second electrode support 26 and the second electrode 13. The second electrode support 26 and the second electrode 13 may be rotated about a rotation axis (central axis) of the substrate W held by the substrate holder 11 by the second electrode mover 28.

The power applying device 16 has a power application terminal 35 and a power source 37. The power source 37 is connected to the first electrode 12, and is also connected to the second electrode 13 via the power application terminal 35.

Under the control of the controller 93, the power applying device 16 applies a power via the first electrode 12 and the second electrode 13 to the processing surface Ws of the substrate W held by the substrate holder 11. That is, as will be described later, in the state that the first electrode 12 is in contact with the substrate W and the second electrode 13 is connected to the substrate W through a plating liquid, the power source 37 applies the power to the substrate W (particularly, the processing surface Ws). A voltage value and a current value of the power supplied by the power applying device 16 may be set as required according to a recipe prepared.

In the example shown in FIG. 2, the power source 37 is connected to the second electrode 13 through the single power application terminal 35. However, the power source 37 may be connected to the second electrode 13 through a plurality of power application terminals 35.

As a distance from the power application terminal 35 increases, the degree of the voltage drop caused by the electrical resistance of the second electrode 13 increases, which raises a tendency for a deposition rate of a plating metal on the processing surface Ws of the substrate W to slow down. Therefore, in the case where the plurality of power application terminals 35 are provided, by discretely arranging the plurality of power application terminals 35 throughout the second electrode 13, the voltage drop can be reduced over the entire second electrode 13, so that uniformization of the deposition rate of the plating metal over the entire processing surface Ws can be accelerated.

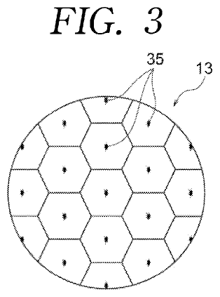

FIG. 3 presents an enlarged plan view of a part of the second electrode 13, showing an example layout of the plurality of power application terminals 35. In the example shown in FIG. 3, the second electrode 13 is divided into a plurality of virtual segments each having a regular hexagonal planar shape, and each power application terminal 35 is connected to a center of the corresponding one of the virtual segments. The size of each virtual segment is appropriately determined in consideration of the electrical resistance of the second electrode 13.

In this way, by disposing each power application terminal 35 at a generatrix of the corresponding virtual segment having the polygonal planar shape, the voltage drop in the second electrode 13 is suppressed, and it becomes possible to apply a uniform voltage to the entire second electrode 13.

The seal member 14 (see FIG. 2) is disposed to surround the processing surface Ws of the substrate W held by the substrate holder 11, thus suppressing a liquid (particularly, the plating liquid) from leaking from the processing surface Ws.

The seal member 14 shown in FIG. 2 has an annular planar shape, and is pressed into contact with the outer peripheral portion of the top surface of the substrate W, surrounding the entire processing surface Ws that is formed by the top surface (except the outer peripheral portion) of the substrate W. The seal member 14 in the present exemplary embodiment is movably supported by the first electrode support 25, and is moved as one body with the first electrode 12.

The plating liquid supply 15 is configured to supply the plating liquid to the processing surface Ws of the substrate W held by the substrate holder 11. In the processing device 10 of the present example, since an electrolytic plating processing is performed on the substrate W, the plating liquid containing no reducing agent is supplied from the plating liquid supply 15 to the processing surface Ws of the substrate W.

The plating liquid supply 15 shown in FIG. 2 includes a plating liquid source 31, a plating liquid supply nozzle 33 connected to the plating liquid source 31 via a plating liquid supply path 30, and a plating liquid supply valve 32 provided in the plating liquid supply path 30.

The plating liquid supply nozzle 33 shown in FIG. 2 is provided to penetrate central portions of the second electrode 13 and the second electrode support 26, and is supported by the second electrode support 26 and configured to be moved as one body with the second electrode 13. However, the providing of the plating liquid supply nozzle 33 is not limited to the shown example, and the plating liquid supply nozzle 33 may be located at a position (for example, an outer edge portion of the second electrode 13) other than the central portion of the second electrode 13. Additionally, a mesh-shaped second electrode 13 or a second electrode 13 provided with a plurality of holes formed by punching may be provided at a leading end (that is, a discharge opening) of the plating liquid supply nozzle 33.

The plating liquid supply valve 32 is configured to adjust opening and closing of the plating liquid supply path 30 as well as the opening degree thereof under the control of the controller 93, so that discharge/stop of the discharge of the plating liquid from the plating liquid supply nozzle 33 is switched and a discharge amount of the plating liquid is varied.

With the seal member 14 pressed against the processing surface Ws of the substrate W, the plating liquid is discharged from the plating liquid supply nozzle 33 toward a region of the processing surface Ws surrounded by the seal member 14 (for example, the central portion of the processing surface Ws), so that the liquid film of the plating liquid is formed on the processing surface Ws.

The processing liquid supply 17 supplies a processing liquid other than the plating liquid to the processing surface Ws of the substrate W held by the substrate holder 11. The processing liquid supply 17 is movably supported by a processing liquid mover 29, and is moved between a position where it supplies the processing liquid to the processing surface Ws and a position where it stands by while the processing liquid is not supplied to the processing surface Ws.

The composition and the use of the processing liquid discharged from the processing liquid supply 17 are not particularly limited. The processing liquid supply 17 may discharge multiple kinds of processing liquids for multiple purposes. When the processing liquid supply 17 discharges the multiple kinds of processing liquids, the processing liquid supply 17 may discharge two or more kinds of processing liquids from individual nozzles or from a common nozzle. When the processing liquid supply 17 discharges the multiple kinds of processing liquids, the processing liquid supply 17 and the processing liquid mover 29 may be provided for each of the processing liquids individually. The processing liquid discharged from the processing liquid supply 17 to be supplied to the processing surface Ws of the substrate W may be, by way of example, a pre-processing liquid for use in a pre-processing of the substrate W performed prior to the plating processing, or may be a post-processing liquid for use in a post-processing of the substrate W performed after the plating processing.

In the above-described processing device 10, the controller 93 outputs controls signals to control the plating liquid supply 15 and the power applying device 16 to perform a second electrolytic plating processing after performing a first electrolytic plating processing.

The first electrolytic plating processing is a plating processing in which the power is applied to the processing surface Ws of the substrate W in the state that the plating liquid is in contact with only a first facing range, which is a partial area of the electrode facing surface 13s of the second electrode 13.

Meanwhile, the second electrolytic plating processing involves applying the power to the processing surface Ws of the substrate W in the state that the plating liquid is in contact with a second facing range (particularly, which includes the first facing range) of the electrode facing surface 13s of the second electrode 13, which is wider than the first facing range.

In the first electrolytic plating processing, the plating processing on a first processing region of the processing surface Ws of the substrate W facing the first facing range can be accelerated more than the plating processing on the other regions of the processing surface Ws. Thus, by setting a region of the substrate W located far from the position to be in contact with the first electrode 12 (in this example, the central region of the processing surface Ws) as the first processing region, a discrepancy in the film thickness of the plating metal on the processing surface Ws caused by the voltage drop can be reduced.

Now, a specific embodiment of a plating method (substrate liquid processing method) will be discussed.

### First Exemplary Embodiment

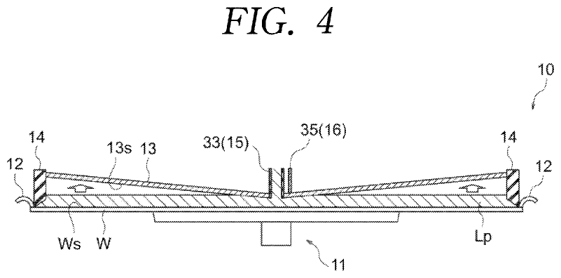

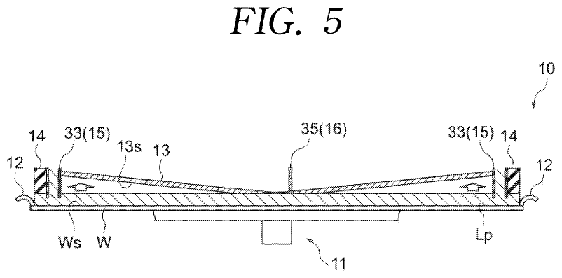

FIG. 4 is a diagram illustrating an example of the processing device 10 according to a first exemplary embodiment. FIG. 5 is a diagram illustrating another example of the processing device 10 according to the first exemplary embodiment. In FIG. 4 and FIG. 5, only some of the components constituting the processing device 10 are shown, while the others are omitted.

In the present exemplary embodiment, in the electrode facing surface 13s of the second electrode 13, the range corresponding to the central region of the processing surface Ws of the substrate W held by the substrate holder 11 is protruded toward the processing surface Ws of the substrate W. That is, a central region of the electrode facing surface 13s is located relatively close to the processing surface Ws, whereas an outer peripheral region of the electrode facing surface 13s is positioned relatively far from the processing surface Ws.

The second electrode 13 (particularly, the electrode facing surface 13s) whose cross section is shown in FIG. 4 and FIG. 5 has a flat portion that is linearly inclined between the central region and the outer peripheral region, but the shape of the portion of the second electrode 13 between the central region and the outer peripheral region is not particularly limited. For example, on the cross section of the second electrode 13, the electrode facing surface 13s may have a smooth curved portion or a step-shaped portion between the central region and the outer peripheral region.

In the present exemplary embodiment, a supply position of the plating liquid Lp from the plating liquid supply nozzle 33 (plating liquid supply 15) is not particularly limited. Furthermore, the number of the plating liquid supply nozzle 33 configured to supply the plating liquid Lp to the processing surface Ws of the substrate W is not specifically limited, either.

For example, as illustrated in FIG. 4, the plating liquid Lp may be supplied to the central region of the processing surface Ws of the substrate W from the single plating liquid supply nozzle 33 provided in the central region (particularly on the central axis) of the second electrode 13. The plating liquid supply nozzle 33, which is positioned to face the central region of the processing surface Ws of the substrate W held by the substrate holder 11, is capable of discharging the plating liquid Lp in a vertical direction toward the central region (for example, onto the central axis) of the processing surface Ws.

Alternatively, as shown in FIG. 5, the plating liquid Lp may be supplied to the outer peripheral region of the processing surface Ws of the substrate W from a plurality of plating liquid supply nozzles 33 provided in the outer peripheral region of the second electrode 13. The plating liquid supply nozzle 33, which is positioned to face the outer peripheral region of the processing surface Ws of the substrate W held by the substrate holder 11, is capable of discharging the plating liquid Lp toward the outer peripheral region of the processing surface Ws. Discharging the plating liquid Lp from the plurality of plating liquid supply nozzles 33 spaced apart from each other as shown in FIG. 5 is advantageous to raise a liquid surface of a liquid puddle of the plating liquid Lp, which is formed on the processing surface Ws, uniformly over the entire processing surface Ws.

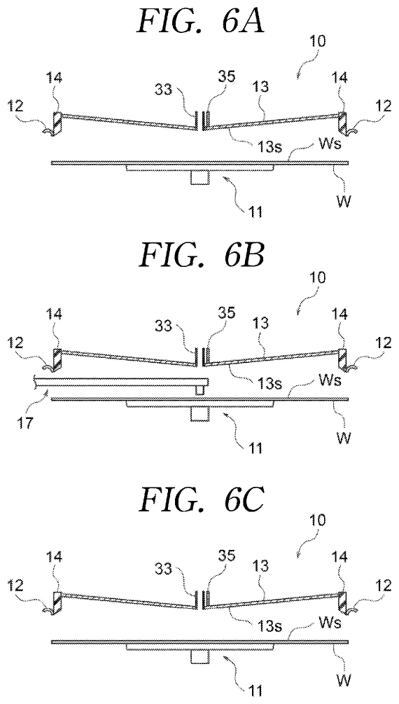

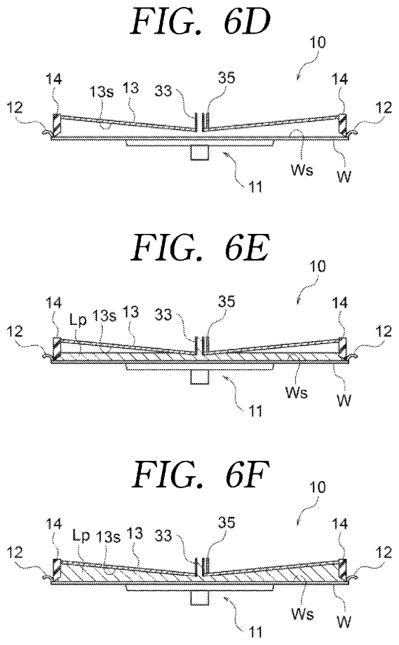

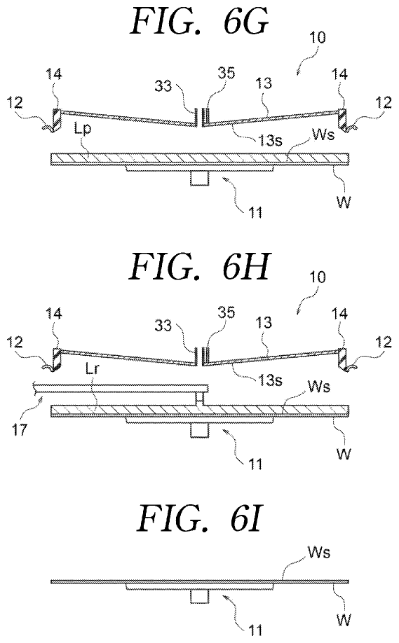

FIG. 6A to FIG. 6I are diagrams showing an example of a plating method (substrate liquid processing method) according to the first exemplary embodiment.

In FIG. 6A to FIG. 6I, only some of the components constituting the processing device 10 are shown, while the others are omitted. Further, although the processing device 10 shown in FIG. 4 is used in FIG. 6A to FIG. 6I, the plating method can be carried out in the same manner even when another processing device 10 (for example, the processing device 10 shown in FIG. 5) is used.

The plating method to be described below is performed as the individual devices constituting the processing device 10 (substrate liquid processing apparatus) are appropriately operated under the control of the controller 93.

First, the substrate W is received and held by the substrate holder 11 (FIG. 6A). At this time, the first electrode 12, the second electrode 13, the seal member 14, and the plating liquid supply nozzle 33 are disposed at the retreat positions away from the substrate W.

Thereafter, when necessary, the processing liquid is supplied from the processing liquid supply 17 to the processing surface Ws of the substrate W, so that the pre-processing (for example, cleaning processing) of the processing surface Ws is performed (FIG. 6B).

Subsequently, when necessary, the processing liquid is removed from the processing surface Ws, so that the processing surface Ws is dried (FIG. 6C). In the present exemplary embodiment, the substrate W is rotated by the substrate holder 11 to remove the processing liquid and dry the processing surface Ws.

While the above-described pre-processing and drying processing of the processing surface Ws are being performed, the first electrode 12, the second electrode 13, the seal member 14, and the plating liquid supply nozzle 33 are kept at the retreat positions.

Thereafter, the first electrode 12, the second electrode 13, the seal member 14, and the plating liquid supply nozzle 33 are placed at the processing positions (FIG. 6D). As a result, the first electrode 12 and the seal member 14 are positioned to be in contact with the outer peripheral portion of the substrate W, and the electrode facing surface 13s of the second electrode 13 is positioned close to the processing surface Ws of the substrate W to face the processing surface Ws with a gap therebetween. As a result, a closed space defined by the substrate W, the seal member 14, and the second electrode 13 is created above the processing surface Ws. In particular, the seal member 14 is pressed against the top surface of the substrate W, so the seal member 14 and the substrate W are placed in a liquid-tight state.

Afterwards, the plating liquid Lp is discharged from the plating liquid supply nozzle 33 disposed at the processing position toward the closed space above the processing surface Ws, so the processing surface Ws of the substrate W is supplied with the plating liquid Lp. A supply rate (flow velocity) of the plating liquid Lp from the plating liquid supply nozzle 33 can be changed by the plating liquid supply 15 (plating liquid supply valve 32 (see FIG. 2)) under the control of the controller 93, and it can be set as required according to a recipe prepared in advance.

The plating liquid Lp supplied from the plating liquid supply nozzle 33 onto the processing surface Ws is blocked by the seal member 14 and accumulated on the processing surface Ws to form a liquid film.

Additionally, while the plating liquid Lp is being applied to the processing surface Ws of the substrate W, a surface layer (seed layer) of the processing surface Ws may react with the plating liquid Lp to be dissolved. From the viewpoint of suppressing the dissolution of the surface layer of the processing surface Ws, it is desirable to accelerate growth of the plating metal on the processing surface Ws by applying the power to the processing surface Ws from the initial stage of the supply of the plating liquid Lp to the processing surface Ws.

For example, the controller 93 may output control signals to control the plating liquid supply 15 and the power applying device 16 to start the supply of the plating liquid Lp to the processing surface Ws after starting the application of the power to the processing surface Ws. In this case, concurrently with the start of the supply of the plating liquid Lp to the processing surface Ws, deposition of the plating metal by a plating reaction is accelerated on the processing surface Ws. As a result, it is possible to suppress the surface layer of the processing surface Ws from being eluted into the plating liquid Lp.

Then, along with the supply of the plating liquid Lp from the plating liquid supply nozzle 33, a liquid level of the liquid puddle of the plating liquid Lp on the processing surface Ws gradually rises, and the plating liquid Lp reaches a height position where it comes into contact with the electrode facing surface 13s of the second electrode 13 (FIG. 6E). As described above, the electrode facing surface 13s of the present exemplary embodiment is located relatively close to the processing surface Ws in its central region. For this reason, only a part (that is, the central region) of the electrode facing surface 13s is locally immersed in the plating liquid Lp first.

In this way, with the electrode facing surface 13s of the second electrode 13 partially in contact with the plating liquid Lp, the power is applied to the processing surface Ws of the substrate W by the power applying device 16, so that the first electrolytic plating processing is performed. That is, in the state that the first electrode 12 is in contact with the substrate W and the plating liquid Lp is in contact with the partial range (first facing range) of the electrode facing surface 13s of the second electrode 13 disposed at a position facing the processing surface Ws, the power flows to the processing surface Ws via the first electrode 12 and the second electrode 13.

As a result, the deposition of the plating metal due to the electrolytic plating reaction proceeds locally in a range of the processing surface Ws facing the first facing range of the electrode facing surface 13s.

The position and the size of the first facing range of the electrode facing surface 13s are not particularly limited. However, the first facing range is determined to cover a range of the processing surface Ws in which the deposition of the plating metal becomes relatively slow due to the voltage drop. Thus, the range including the center of the electrode facing surface 13s (that is, the range facing the central region of the processing surface Ws of the substrate W) is set as the first facing range.

Actually, the power flows throughout the entire processing surface Ws even in the first electrolytic plating processing. As a result, the plating metal may also be deposited on a portion of the processing surface Ws facing a portion of the electrode facing surface 13s that is not immersed in the plating liquid Lp. However, the deposition of the plating metal progresses more actively at a portion of the processing surface Ws facing a portion of the electrode facing surface 13s that is immersed in the plating liquid Lp, as compared to the portion of the processing surface Ws facing the portion of the electrode facing surface 13s that is not immersed in the plating liquid Lp.

The controller 93 may output control signals to control the plating liquid supply 15 and the power applying device 16 such that the supply of the plating liquid Lp to the processing surface Ws may be stopped at least in a part of the time during which the first electrolytic plating processing is being performed. That is, the supply of the plating liquid Lp into the closed space above the processing surface Ws may be first stopped before the plating liquid Lp comes into contact with a maximum electrode contact range, which is a maximum range of the electrode facing surface 13s to be in contact with the plating liquid Lp.

Alternatively, the controller 93 may output controls signals to control the plating liquid supply 15 and the power applying device 16 such that the supply of the plating liquid Lp to the processing surface Ws is carried on without being stopped while the first electrolytic plating processing is being performed. In this case, the first facing range of the electrode facing surface 13s that comes into contact with the plating liquid Lp during the first electrolytic plating processing changes with a lapse of time and gradually widens.

Then, while applying the power to the processing surface Ws of the substrate W, the plating liquid Lp is additionally supplied to the processing surface Ws from the plating liquid supply nozzle 33. Accordingly, the range of the electrode facing surface 13s of the second electrode 13 immersed in the plating liquid Lp is gradually expanded. As the supply of the plating liquid Lp from the plating liquid supply nozzle 33 progresses in this way, the range of the electrode facing surface 13s immersed in the plating liquid Lp is gradually expanded, and, as a result, the range of the processing surface Ws on which the plating metal is actively deposited is gradually expanded.

Then, once the plating liquid Lp comes into contact with the maximum electrode contact range of the electrode facing surface 13s, the discharge of the plating liquid Lp from the plating liquid supply nozzle 33 is stopped, so the supply of the plating liquid Lp to the closed space above the processing surface Ws is ended (FIG. 6F).

The maximum electrode contact range referred to here is typically the entire electrode facing surface 13s, and as the closed space above the processing surface Ws is completely filled with the plating liquid Lp, the entire electrode facing surface 13s comes into contact with the plating liquid Lp.

However, the maximum electrode contact range does not necessarily need to be the entire electrode facing surface 13s. The supply of the plating liquid Lp to the closed space from the plating liquid supply nozzle 33 may be terminated in the state that a part of the closed space above the processing surface Ws still remains empty. In this case, an outer edge portion of the electrode facing surface 13s does not come into contact with the plating liquid Lp.

The controller 93 in the present exemplary embodiment outputs a control signal to control the plating liquid supply 15 (plating liquid supply valve 32) such that the entire maximum electrode contact range is in contact with the plating liquid by taking five seconds or more after the supply of the plating liquid Lp to the processing surface Ws is started. For example, the entire maximum electrode contact range may be in contact with the plating liquid Lp by taking ten seconds or more, one minute or more, or 10 minutes or more (typically, about 10 seconds to 5 minutes) after the start of the supply of the plating liquid Lp to the processing surface Ws.

In the present exemplary embodiment, from the start of the supply of the plating liquid Lp to the processing surface Ws until a preset time elapses after the supply of the plating liquid Lp to the processing surface Ws is stopped, the power is continuously applied to the processing surface Ws by the power applying device 16, so that the deposition of the plating metal on the processing surface Ws is accelerated continuously. In this way, the state in which the plating liquid Lp is in contact with the maximum electrode contact range of the electrode facing surface 13s and the power flows in the processing surface Ws is continued for some time.

Then, when the deposition of the plating metal on the processing surface Ws is sufficiently performed, the application of the power to the processing surface Ws is stopped, so the plating processing on the processing surface Ws is completed.

The controller 93 in the present exemplary embodiment outputs the control signals such that the series of processes of the plating processing described above are performed as follows.

That is, the time during which the power is applied to the processing surface Ws in the state that the plating liquid Lp is in contact with the maximum electrode contact range of the electrode facing surface 13s is referred to as ‘Tm’. Further, the time during which the power is applied to the processing surface Ws in the state that the plating liquid Lp is in contact with a range of the electrode facing surface 13s narrower than the maximum electrode contact range is referred to as ‘Tn’. In this case, the controller 93 performs the plating processing by controlling the power applying device 16 (for example, the power source 37) such that the time Tn is longer than the time Tm (i.e., ‘Tn>Tm’ is satisfied).

Upon the completion of the plating processing, the first electrode 12, the second electrode 13, the seal member 14, and the plating liquid supply nozzle 33 are placed at the retreat positions (FIG. 6G).

Afterwards, a rinse liquid Lr (for example, DIW (Deionized water)) is supplied to the processing surface Ws of the substrate W by the processing liquid supply 17, so that the plating liquid Lp is washed away from the processing surface Ws (FIG. 6H; rinsing processing).

Thereafter, the substrate W is rotated by the substrate holder 11 to dry (spin-dry) the processing surface Ws (FIG. 6I; drying processing). Further, the second electrode 13 (particularly the electrode facing surface 13s), the seal member 14, and the first electrode 12 are appropriately cleaned at the retreat positions.

As described above, according to the present exemplary embodiment, in the initial stage of the plating processing, the film formation of the plating metal at the central region of the processing surface Ws of the substrate W can be intensively accelerated in the state that only the partial region (central region) of the electrode facing surface 13s of the second electrode 13 is in contact with the plating liquid Lp. Then, by gradually supplying the plating liquid Lp to the closed space above the processing surface Ws in the state that the processing surface Ws is supplied with the power, the range of the second electrode 13 immersed in the plating liquid Lp is gradually expanded toward the outer peripheral portion thereof, so that the range of the second electrode 13 contributing to the electrolytic plating is gradually expanded toward the outer peripheral portion thereof. Then, in the final stage of the plating processing, the film formation of the plating metal on the entire processing surface Ws is accelerated.

Accordingly, the influence of the “decrease of the deposition rate of the plating metal at the central region of the processing surface Ws” caused by the voltage drop in the plating processing may be reduced due to the “local acceleration of the deposition of the plating metal at the central region of the processing surface Ws” in the initial stage of the plating processing. In this way, by expanding the deposition range of the plating metal gradually from the center side of the processing surface Ws toward the outer peripheral side thereof, the plating metal can ultimately be deposited in the appropriate film thickness on the entire processing surface Ws. That is, in the stage when the plating processing is completed, the difference in the film thickness of the plating metal between the central region and the outer peripheral region of the processing surface Ws can be reduced, so that the uniformity of the film thickness of the plating metal deposited on the substrate W can be improved.

In addition, by adjusting the supply rate of the plating liquid Lp from the plating liquid supply nozzle 33 into the closed space above the processing surface Ws according to the voltage drop characteristics in the plating processing, the uniformity of the film thickness of the plating metal on the processing surface Ws can be improved more effectively.

Conventionally, it has been attempted to improve the uniformity of the film thickness of the plating metal by reducing the difference in plating reaction time between the respective regions of the processing surface Ws, and the plating liquid Lp is diffused to the entire processing surface Ws in a short time after the supply of the plating liquid Lp is begun. That is, conventionally, it has been attempted to uniformize the film thickness of the plating metal on the processing surface Ws by minimizing the time from the start of the supply of the plating liquid Lp to the processing surface Ws until the entire processing surface Ws is covered with the plating liquid Lp.

Meanwhile, in the present exemplary embodiment, the range of the second electrode 13 (electrode facing surface 13s) that comes into contact with the plating liquid Lp on the processing surface Ws is expanded gradually or continuously over time. Accordingly, actual plating reaction time actively changes between the respective regions of the processing surface Ws based on the intensity of the original electrolytic plating reaction according to the voltage drop characteristic, so that the film thickness of the plating metal on the processing surface Ws is uniformized.

Furthermore, even when it is difficult to sufficiently deposit the plating metal at the central portion of the processing surface Ws in the conventional method because of large electrical resistance of the surface layer (seed layer) of the processing surface Ws, it is still possible, according to the present exemplary embodiment, to deposit the plating metal sufficiently at the central portion of the processing surface Ws.

### Second Exemplary Embodiment

In a second exemplary embodiment, parts identical or corresponding to those of the first exemplary embodiment will be assigned same reference numerals, and redundant description thereof will be omitted.

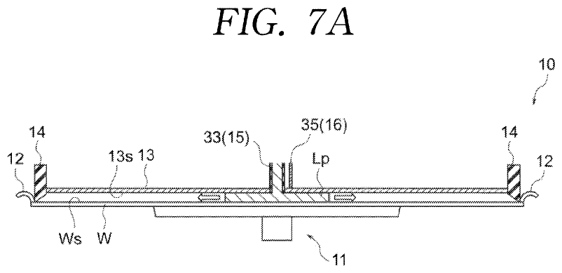

FIG. 7A is a diagram illustrating an example of the processing device 10 according to the second exemplary embodiment. In FIG. 7A, only some of the components constituting the processing device 10 are shown, while the others are omitted. FIG. 7B is a diagram showing an example of a planar state of the substrate W, illustrating how the plating liquid Lp on the substrate W is diffused in the processing device 10 shown in FIG. 7A.

In the processing device 10 shown in FIG. 7A, the second electrode 13 has a flat plate shape, and the electrode facing surface 13s extends parallel to the horizontal direction. However, the specific shape of the second electrode 13 (for example, the electrode facing surface 13s) is not particularly limited.

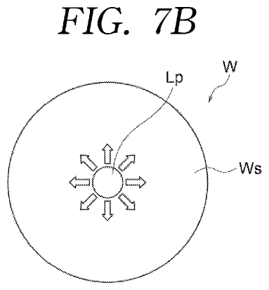

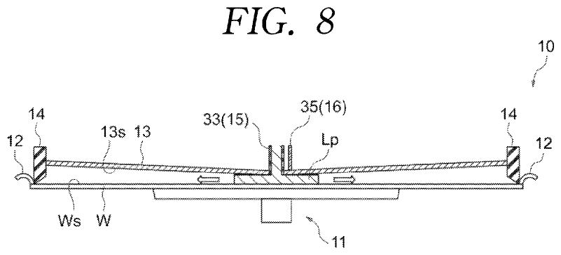

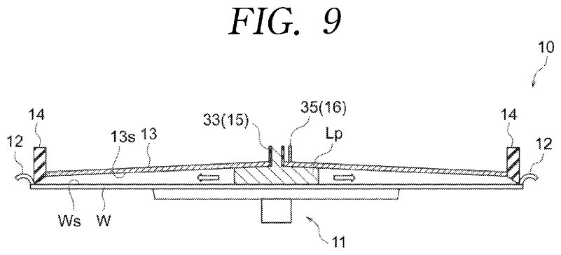

FIG. 8 and FIG. 9 are diagrams showing another example of the processing device 10 according to the second exemplary embodiment.

For example, as illustrated in FIG. 8, the central region of the electrode facing surface 13s may have a downwardly convex shape as compared to the outer edge portion of the electrode facing surface 13s. In this case, the region of the electrode facing surface 13s facing the center region of the processing surface Ws of the substrate W held by the substrate holder 11 is protruded toward the processing surface Ws. In the example shown in FIG. 8, since the closed space directly above the central region of the processing surface Ws of the substrate W is small, the plating liquid Lp supplied from the plating liquid supply nozzle 33 can be easily diffused onto the processing surface Ws. Further, in the example shown in FIG. 8, the distance between the central region of the processing surface Ws of the substrate W and the second electrode 13 can be shortened, so that the deposition of the plating metal at the central region of the processing surface Ws can be efficiently accelerated.

Alternatively, as shown in FIG. 9, the central region of the electrode facing surface 13s may have a downwardly concave shape as compared to the outer edge portion of the electrode facing surface 13s. In this case, the range of the electrode facing surface 13s facing the central region of the processing surface Ws of the substrate W held by the substrate holder 11 is recessed with respect to the processing surface Ws. In the example shown in FIG. 9, since the closed space directly above the central region of the processing surface Ws of the substrate W is large, the plating liquid Lp supplied from the plating liquid supply nozzle 33 can be slowly diffused on the processing surface Ws. Thus, it is easy to control the diffusion state of the plating liquid Lp on the processing surface Ws.

The plating liquid supply nozzle 33 is provided in the central region of the second electrode 13, the same as in the example shown in FIG. 4 described above, and supplies the plating liquid Lp on the central region of the processing surface Ws. Accordingly, the plating liquid Lp is gradually diffused outwards from the central region of the processing surface Ws while coming into contact with the processing surface Ws and the electrode facing surface 13s. That is, the plating liquid Lp supplied to the processing surface Ws partially comes into contact with both the central region of the electrode facing surface 13s and the central region of the processing surface Ws before it is diffused onto the entire processing surface Ws. Then, the plating liquid Lp gradually expands the range of the contact with the processing surface Ws and the electrode facing surface 13s while maintaining the contact with the processing surface Ws and the electrode facing surface 13s.

Further, a gap between the second electrode 13 (electrode facing surface 13s) and the substrate W (processing surface Ws) is set to a distance (for example, about 1 mm to about 3 mm) at which the liquid puddle of the plating liquid Lp is kept between the processing surface Ws and the electrode facing surface 13s by a surface tension of the plating liquid Lp.

In this example, with the first electrode 12, the second electrode 13, the seal member 14, and the plating liquid supply nozzle 33 placed at the processing positions, the plating liquid Lp is supplied from the plating liquid supply nozzle 33 to the closed space above the processing surface Ws, so that the first electrolytic plating processing is performed. That is, with the plating liquid Lp in contact with the first facing range, which is a partial range of the electrode facing surface 13s, the power is applied to the processing surface Ws, so that the first electrolytic plating processing is carried out.

Further, in the above-described first exemplary embodiment, the controller 93 outputs the control signal such that the first electrolytic plating processing is performed in the state that the plating liquid Lp is in contact with the whole of the maximum range (maximum substrate contact range) of the processing surface Ws supposed to be in contact with the plating liquid Lp, as shown in FIG. 4.

Meanwhile, in the present exemplary embodiment, the controller 93 outputs a control signal such that the first electrolytic plating processing is performed in the state that the plating liquid Lp is in contact with on a part of the maximum substrate contact range of the processing surface Ws, as illustrated in FIG. 7A to FIG. 9.

Further, in the present exemplary embodiment, by starting the application of the power to the processing surface Ws prior to the application of the plating liquid Lp to the processing surface Ws, elution of the surface layer (seed layer) of the processing surface Ws into the plating liquid Lp can be suppressed, the same as in the above-described first exemplary embodiment.

Thereafter, the plating liquid Lp is supplied from the plating liquid supply nozzle 33 onto the processing surface Ws. The power is applied to the processing surface Ws in the state that the plating liquid Lp is supplied on the entire processing surface Ws, so that the plating processing is performed. In the present exemplary embodiment, the entire closed space above the processing surface Ws is filled with the plating liquid Lp. Thus, the plating processing is performed in the state that the plating liquid Lp is in contact with the whole (maximum electrode contact range) of the electrode facing surface 13s of the second electrode 13.

In addition, the electrode facing surface 13s of the second electrode 13 may have a configuration that allows the plating liquid Lp on the processing surface Ws of the substrate W (that is, the plating liquid Lp on the electrode facing surface 13s) to be uniformly diffused in a radial direction from the center of the processing surface Ws.

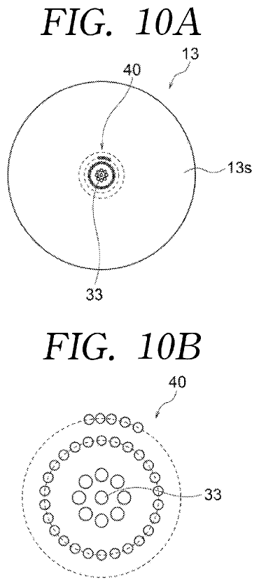

FIG. 10A is a plan view illustrating an example of the second electrode 13. FIG. 10B is an enlarged view illustrating an example of an irregularity pattern 40 shown in FIG. 10A.

The electrode facing surface 13s may have, for example, the irregularity pattern 40 formed in concentric circles around the central axis (rotation axis) of the second electrode 13. In the example shown in FIG. 10A and FIG. 10B, the irregularity pattern 40 is formed of a set of punched holes formed in the second electrode 13. A specific configuration of the irregularity pattern 40 is not particularly limited. By way of example, each punched hole may have a diameter ranging from about 0.5 mm to about 1 mm. Further, instead of the punched holes, the irregularity pattern 40 may be formed of a set of fine protrusions (for example, a plurality of fine protrusions having a protrusion height of about 0.5 mm or less).

Instead of the physical irregularity pattern 40, the second electrode 13 (particularly, the electrode facing surface 13s) may include a plurality of materials having different surface properties, thus allowing the plating liquid Lp on the processing surface Ws to be uniformly diffused in the radial direction. For example, the second electrode 13 may include a plurality of materials that have different contact angles with respect to the plating liquid Lp and are arranged concentrically, and the plurality of materials may be arranged concentrically around the central axis of the second electrode 13.

The other configuration of the processing device 10 shown in FIG. 7A is the same as that of the processing device 10 shown in FIG. 4 according to the first exemplary embodiment described above.

Now, an example of a plating method according to the present exemplary embodiment will be described.

In the following, first to third examples of the plating method performed by the processing device 10 shown in FIG. 7A will be described. The processing device 10 (see FIG. 8 to FIG. 10B) having another configuration can also perform the following plating method in the same manner.

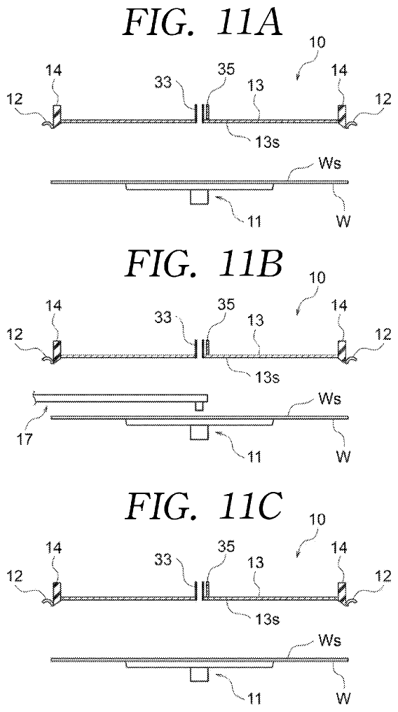

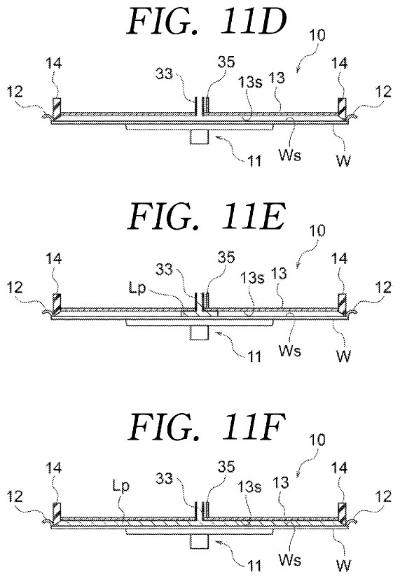

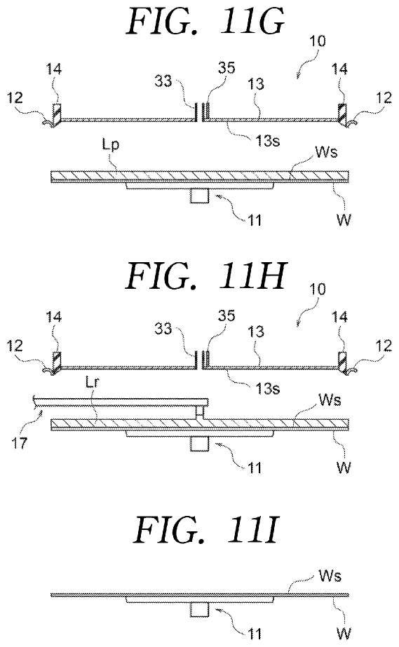

FIG. 11A to FIG. 11I are diagrams showing the first example of the plating method according to the second exemplary embodiment.

In FIG. 11A to FIG. 11I, only some of the components constituting the processing device 10 are shown, while the others are omitted. In this example as well, each processing is performed as the individual devices constituting the processing device 10 (substrate liquid processing apparatus 1) are appropriately operated under the control of the controller 93.

First, the substrate W is received and held by the substrate holder 11 (FIG. 11A).

Afterwards, when necessary, the processing liquid is supplied from the processing liquid supply 17 to the processing surface Ws of the substrate W to perform the pre-processing of the processing surface Ws (FIG. 11B), and the processing liquid is removed from the processing surface Ws to dry the processing surface Ws (FIG. 11C). In the pre-processing of the present example, a chemical reaction of the processing liquid is used to carry out the pre-processing of the processing surface Ws.

Thereafter, the first electrode 12, the second electrode 13, the seal member 14, and the plating liquid supply nozzle 33 are placed at the processing positions (FIG. 11D). Then, the plating liquid Lp is discharged from the plating liquid supply nozzle 33 toward the closed space above the processing surface Ws of the substrate W to be supplied to the processing surface Ws (FIG. 11E). As a result, only a part of the processing surface Ws and only a part of the electrode facing surface 13s locally come into contact with the plating liquid Lp.

In this way, with the electrode facing surface 13s of the second electrode 13 partially in contact with the plating liquid Lp, the power is applied to the processing surface Ws of the substrate W by the power applying device 16, so that the first electrolytic plating processing is performed.

Then, the plating liquid Lp is additionally supplied from the plating liquid supply nozzle 33 to the processing surface Ws of the substrate W, so that the range of the electrode facing surface 13s covered by the plating liquid Lp is gradually expanded.

While the plating liquid Lp is being diffused on the processing surface Ws as described above, the substrate holder 11 may rotate the substrate W, and the second electrode mover 28 may rotate the second electrode 13 via the second electrode support 26. By rotating the substrate W and/or the second electrode 13 in this way, uniform diffusion of the plating liquid Lp in the radial direction can be promoted while bringing the plating liquid Lp into contact with the processing surface Ws and the electrode facing surface 13s. In this case, although the rotation speed of the substrate W and the rotation speed of the second electrode 13 are not particularly limited, they are typically set to be of a value (e.g., several rpm to several tens of rpm) lower than the rotation speed (e.g., 1000 rpm) of the substrate W in the spin-drying processing.

Then, when the plating liquid Lp comes into contact with the maximum electrode contact range of the electrode facing surface 13s, the discharge of the plating liquid Lp from the plating liquid supply nozzle 33 is stopped, so that the supply of the plating liquid Lp to the closed space above the processing surface Ws is ended (FIG. 11F).

In the present example, from the start of the supply of the plating liquid Lp to the processing surface Ws until a predetermined time elapses after the supply of the plating liquid Lp to the processing surface Ws is stopped, the power is continuously applied to the processing surface Ws by the power applying device 16, so that the plating metal is continuously deposited on the processing surface Ws.

Then, when the deposition of the plating metal on the processing surface Ws is sufficiently performed, the application of the power to the processing surface Ws is stopped to end the plating processing on the processing surface Ws, and the first electrode 12, the second electrode 13, the seal member 14, and the plating liquid supply nozzle 33 are disposed at the retreat positions (FIG. 11G).

Afterwards, the rinse liquid Lr is supplied to the processing surface Ws of the substrate W by the processing liquid supply 17 to wash away the plating liquid Lp from the processing surface Ws (FIG. 11H), and the substrate W is rotated by the substrate holder 11, so that the processing surface Ws is dried (FIG. 11I). Meanwhile, the second electrode 13 (particularly, the electrode facing surface 13s), the seal member 14, and the first electrode 12 are appropriately cleaned at the retreat positions.

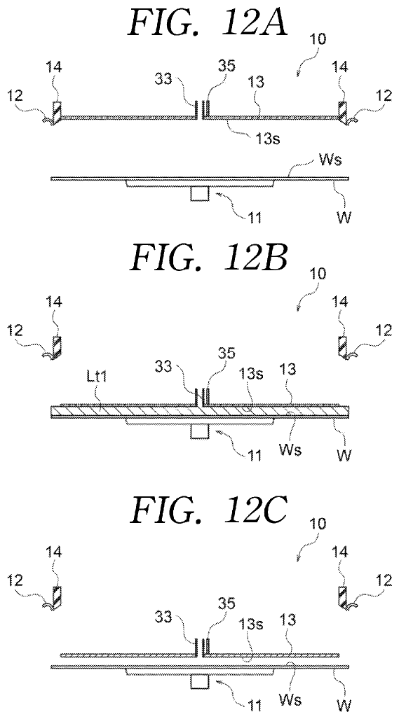

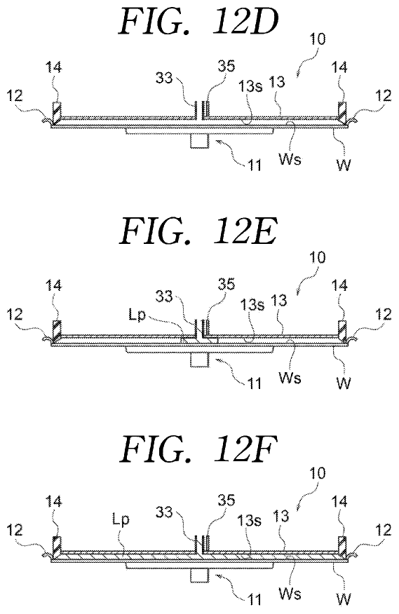

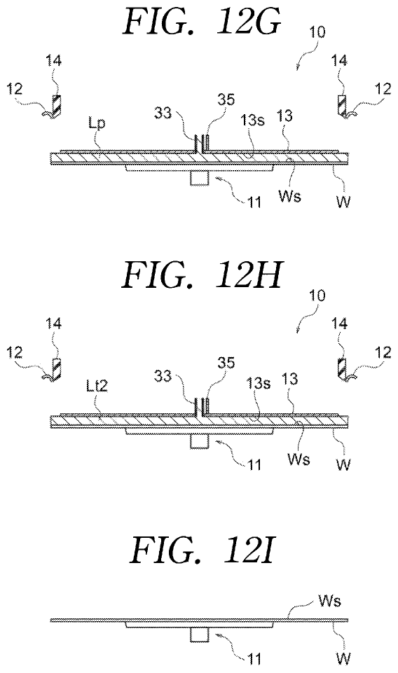

FIG. 12A to FIG. 12I are diagrams showing the second example of the plating method according to the second exemplary embodiment. In FIG. 12A to FIG. 12I, only some of the components constituting the processing device 10 are shown, while the others are omitted.

In the present example, after the substrate W is held by the substrate holder 11 (FIG. 12A), the pre-processing is performed in the state that the second electrode 13 and the plating liquid supply nozzle 33 are placed at the processing positions (FIG. 12B).

That is, the pre-processing is performed in the state that a pre-processing liquid Lt1 is in contact with the processing surface Ws of the substrate W and the electrode facing surface 13s of the second electrode 13. Accordingly, the pre-processing of both the processing surface Ws and the electrode facing surface 13s can be performed at once. In the pre-processing of the present example, a chemical reaction of the processing liquid is used to carry out the pre-processing of the processing surface Ws and the electrode facing surface 13s.

In the example shown in FIG. 12B, while the pre-processing is being performed, the seal member 14 and the first electrode 12 are disposed at the retreat positions.

Further, in the example shown in FIG. 12B, the pre-processing liquid Lt1 for the pre-processing is supplied onto the processing surface Ws via the plating liquid supply nozzle 33 rather than the processing liquid supply 17 (see FIG. 2). In this way, the plating liquid supply nozzle 33 in the present example not only functions as the plating liquid supply 15 but also functions as the processing liquid supply 17.

A supply system (not shown) of the pre-processing liquid Lt1 may be connected to the plating liquid supply nozzle 33 in any of various ways. As an example, a flow path switching valve may be provided in a common flow path connected to the plating liquid supply nozzle 33, and the liquid to be supplied to the plating liquid supply nozzle 33 may be switched by the flow path switching valve between the plating liquid Lp and the pre-processing liquid Lt1.

Thereafter, the substrate holder 11 rotates the substrate W to remove the pre-processing liquid Lt1 from the processing surface Ws, so that the processing surface Ws is dried (FIG. 12C). In this drying processing, in the example shown in FIG. 12C, the second electrode 13 and the plating liquid supply nozzle 33 remain at the processing positions, and the seal member 14 and the first electrode 12 remain at the retreat positions.

Subsequently, the first electrode 12, the second electrode 13, the seal member 14, and the plating liquid supply nozzle 33 are placed at the processing positions (FIG. 12D). Then, the plating liquid Lp is discharged from the plating liquid supply nozzle 33 toward the closed space above the processing surface Ws of the substrate W to be supplied to the processing surface Ws (FIG. 12E).

Then, in the state that only a part of the electrode facing surface 13s and only a part of the processing surface Ws are locally in contact with the plating liquid Lp, the power is applied to the processing surface Ws by the power applying device 16, so that the first electrolytic plating processing is performed.

Thereafter, the plating liquid Lp is additionally supplied from the plating liquid supply nozzle 33 to the processing surface Ws of the substrate W, so that the range of the electrode facing surface 13s covered by the plating liquid Lp is gradually expanded. Then, when the plating liquid Lp comes into contact with the maximum electrode contact range of the electrode facing surface 13s, the discharge of the plating liquid Lp from the plating liquid supply nozzle 33 is stopped, so the supply of the plating liquid Lp to the closed space above the processing surface Ws is ended (FIG. 12F).

In the present example, from the start of the supply of the plating liquid Lp to the processing surface Ws until a predetermined time elapses after the supply of the plating liquid Lp to the processing surface Ws is stopped, the power is continuously applied to the processing surface Ws by the power applying device 16, so that the plating metal is continuously deposited on the processing surface Ws.

Then, when the deposition of the plating metal on the processing surface Ws is sufficiently performed, the application of the power to the processing surface Ws is stopped to end the plating processing on the processing surface Ws, and the first electrode 12 and the seal member 14 are disposed at the retreat positions (FIG. 12G). In the example shown in FIG. 12G, the second electrode 13 and the plating liquid supply nozzle 33 remain at the processing positions.

Afterwards, a post-processing liquid Lt2 (rinse liquid) is supplied to the processing surface Ws of the substrate W by the plating liquid supply nozzle 33, so that the plating liquid Lp is washed away from the processing surface Ws (FIG. 12H). In the example shown in FIG. 12H, the second electrode 13 and the plating liquid supply nozzle 33 remain at the processing positions. Therefore, the plating liquid Lp adhering to the electrode facing surface 13s is also washed away by the post-processing liquid Lt2 along with the plating liquid Lp adhering to the processing surface Ws.

Further, in the example shown in FIG. 12H, the post-processing liquid Lt2 for the post-processing is supplied onto the processing surface Ws via the plating liquid supply nozzle 33 rather than the processing liquid supply 17 (see FIG. 2). A supply system (not shown) of the post-processing liquid Lt2 for use in the post-processing may be connected to the plating liquid supply nozzle 33 in any of various ways. As an example, a flow path switching valve may be provided in a common flow path connected to the plating liquid supply nozzle 33, and the liquid to be supplied to the plating liquid supply nozzle 33 may be switched by the flow path switching valve between the plating liquid Lp and the post-processing liquid Lt2. The post-processing liquid Lt2 may be the same as the pre-processing liquid Lt1, and the pre-processing liquid Lt1 and the post-processing liquid Lt2 may be supplied to the plating liquid supply nozzle 33 by using a common supply system.

Thereafter, with the first electrode 12, the second electrode 13, the seal member 14, and the plating liquid supply nozzle 33 disposed at the retreat positions, the substrate W is rotated by the substrate holder 11, so that the processing surface Ws is dried (FIG. 12I). Meanwhile, the second electrode 13 (particularly, the electrode facing surface 13s), the seal member 14, and the first electrode 12 are appropriately cleaned at the retreat positions.

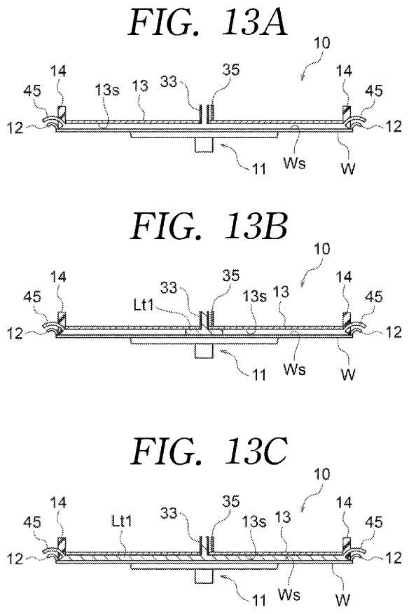

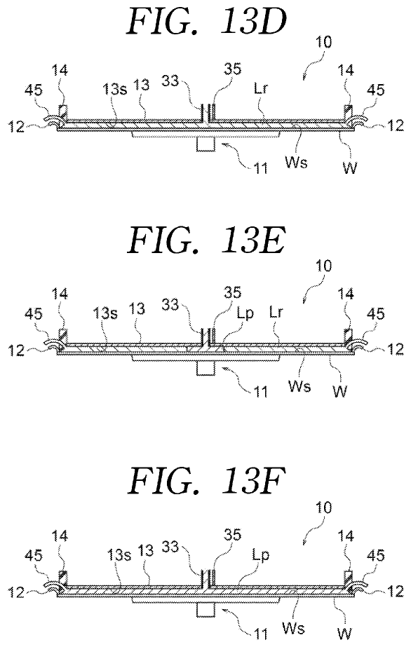

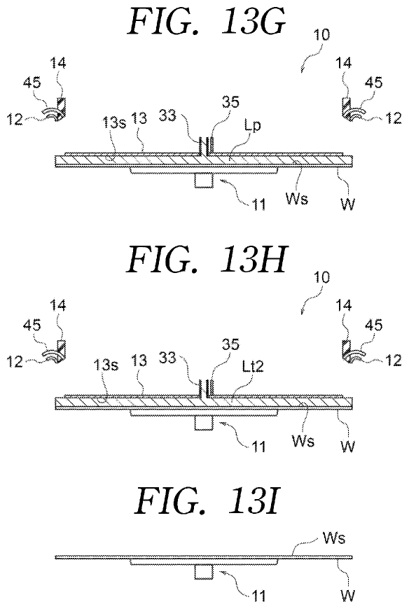

FIG. 13A to FIG. 13I are diagrams illustrating the third example of the plating method according to the second exemplary embodiment. In FIG. 13A to FIG. 13I, only some of the components constituting the processing device 10 are shown, while the others are omitted.

In the present example, after the substrate W is held by the substrate holder 11, the first electrode 12, the second electrode 13, the seal member 14, and the plating liquid supply nozzle 33 are placed at the processing positions (FIG. 13A). Then, with the first electrode 12, the second electrode 13, the seal member 14, and the plating liquid supply nozzle 33 placed at the processing positions, the pre-processing with the pre-processing liquid Lt1 is performed (FIG. 13B and FIG. 13C).

That is, the pre-processing liquid Lt1 is supplied to the processing surface Ws of the substrate W from the plating liquid supply nozzle 33 (FIG. 13B), and the entire closed space above the processing surface Ws is filled with the pre-processing liquid Lt1. Accordingly, the pre-processing liquid Lt1 is applied to the entire processing surface Ws and the entire electrode facing surface 13s (FIG. 13C).

The pre-processing of the present example is performed as the power is applied to the processing surface Ws by the power applying device 16 via the first electrode 12 and the second electrode 13 in the state that the pre-processing liquid Lt1 is in contact with a part or the whole of each of the processing surface Ws and the electrode facing surface 13s. Accordingly, the pre-processing liquid Lt1 causes an electrochemical reduction reaction, so that an oxide on the processing surface Ws and the electrode facing surface 13s is reduced to be removed. Further, prior to the pre-processing of the processing surface Ws by this electrochemical reduction reaction, the processing surface Ws may be subjected to a chemical pre-processing by a certain processing liquid.

Afterwards, the rinse liquid Lr (for example, DIW) is supplied to the processing surface Ws from the plating liquid supply nozzle 33, so that the pre-processing liquid Lt1 is washed away from the processing surface Ws and the electrode facing surface 13s (FIG. 13D).

In the example shown in FIG. 13A to FIG. 13I, a liquid drain 45 is configured to penetrate the seal member 14, allowing the closed space above the processing surface Ws to communicate with the outside through the liquid drain 45. For this reason, as the rinse liquid Lr is supplied to the closed space, the pre-processing liquid Lt1 in the closed space is pushed out to the outside through the liquid drain 45.

Thereafter, the plating liquid Lp is discharged from the plating liquid supply nozzle 33 toward the closed space above the processing surface Ws of the substrate W to be supplied to the processing surface Ws (FIG. 13E). As the plating liquid Lp is supplied to the closed space, the rinse liquid Lr in the closed space is pushed out to the outside through the liquid drain 45.

Then, in the state that a part of the electrode facing surface 13s (that is, the central region of the electrode facing surface 13s near the plating liquid supply nozzle 33) is in contact with the plating liquid Lp, the power is applied to the processing surface Ws of the substrate W by the power applying device 16, so that the first electrolytic plating processing is performed.

In addition, since the plating liquid supply nozzle 33 in this example discharges the plating liquid Lp toward the rinse liquid Lr in the closed space, some of the plating liquid Lp on the processing surface Ws is mixed into the rinse liquid Lr. Accordingly, although some of the plating liquid Lp in the closed space is mixed with the rinse liquid Lr, the first electrolytic plating processing of the present example is performed in the state that most of the plating liquid Lp remains at a position facing the first facing range of the electrode facing surface 13s.

Then, the plating liquid Lp is additionally supplied from the plating liquid supply nozzle 33 to the processing surface Ws of the substrate W, so the range of the electrode facing surface 13s covered by the plating liquid Lp is gradually expanded.

Then, the entire closed space above the processing surface Ws is filled with the plating liquid Lp, and the plating liquid Lp comes into contact with the maximum electrode contact range of the electrode facing surface 13s. Once the plating liquid Lp comes into contact with the maximum electrode contact range of the electrode facing surface 13s, the discharge of the plating liquid Lp from the plating liquid supply nozzle 33 is stopped, so the supply of the plating liquid Lp to the closed space above the processing surface Ws is ended (FIG. 13F).

In the present example, from the start of the supply of the plating liquid Lp to the processing surface Ws until a preset time passes by after the supply of the plating liquid Lp to the processing surface Ws is stopped, the power is continuously applied to the processing surface Ws by the power applying device 16, so that the plating metal is continuously deposited on the processing surface Ws.

Then, when the plating metal is sufficiently deposited on the processing surface Ws, the application of the power to the processing surface Ws is stopped to end the plating processing on the processing surface Ws, and the first electrode 12, the seal member 14, and the liquid drain 45 are disposed at their retreat positions (FIG. 13G). In the example shown in FIG. 13G, the second electrode 13 and the plating liquid supply nozzle 33 remain at the processing positions.

Afterwards, the post-processing liquid Lt2 (rinse liquid) is supplied to the processing surface Ws of the substrate W by the plating liquid supply nozzle 33, so that the plating liquid Lp is washed away from the processing surface Ws and the electrode facing surface 13s (FIG. 13H).

Then, with the second electrode 13 and the plating liquid supply nozzle 33 disposed at the retreat positions, the substrate W is rotated by the substrate holder 11 to dry the processing surface Ws (FIG. 13I). Meanwhile, the second electrode 13 (particularly, the electrode facing surface 13s), the seal member 14, and the first electrode 12 are appropriately cleaned at the retreat positions.

In the above-described present exemplary embodiment as well, in the initial stage of the plating processing, the film formation of the plating metal at the central region of the processing surface Ws of the substrate W can be intensively accelerated in the state that only the central region of the electrode facing surface 13s of the second electrode 13 is in contact with the plating liquid Lp.

In particular, in the initial stage of the plating processing, the plating processing is performed by applying the power to the processing surface Ws in the state that the plating liquid Lp is not adhering to the outer peripheral portion of the processing surface Ws. Therefore, it is possible to reliably suppress the plating metal from being deposited on the outer peripheral portion of the processing surface Ws in the initial stage of the plating processing.

### First Modification Example

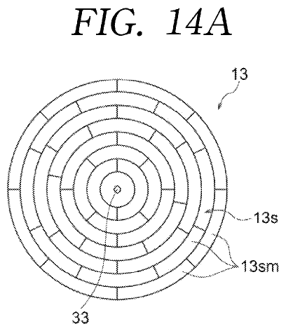

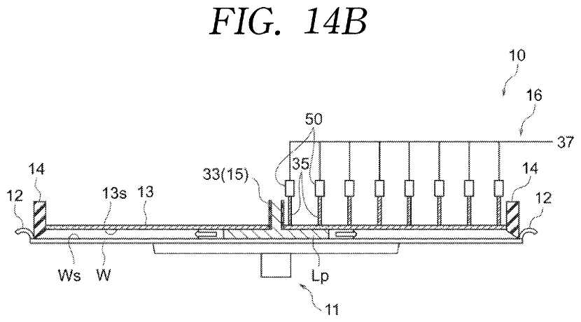

FIG. 14A is a plan view showing the electrode facing surface 13s of the second electrode 13 according to a first modification example. FIG. 14B is a diagram showing the processing device 10 according to the first modification example.

Although the second electrode 13 shown in FIG. 14A and FIG. 14B has a flat plate shape, the present modification example is also applicable to the second electrode 13 of a non-flat plate shape (that is, the electrode facing surface 13s extending in a non-horizontal direction).

The electrode facing surface 13s may be divided into a plurality of division surfaces 13sm. The power applying device 16 may be configured to change the power applied to each of the plurality of division surfaces 13sm independently between the plurality of division surfaces 13sm under the control of the controller 93 (see FIG. 1).

In the example shown in FIG. 14A, the electrode facing surface 13s is divided into concentric circles around the central axis (rotation axis) of the second electrode 13, and each concentric circle-shaped region is divided into multiple sections, thereby defining the plurality of division surfaces 13sm.

Each division surface 13sm is connected to the corresponding power application terminal 35. The power applying device 16 is capable of independently changing the voltages applied to the respective power application terminals 35 under the control of the controller 93.

In the example shown in FIG. 14B, the power application terminals 35 are respectively connected to a power supply 37 via power application adjusters 50. Each power application adjuster 50 adjusts the voltage of the power applied to the corresponding power application terminal 35 under the control of the controller 93.

By way of example, each power application adjuster 50 may include a variable resistor, and a resistance value of the variable resistor may be appropriately changed by the controller 93. In this case, even if the same voltage is applied to the respective power application adjusters 50 by the power applying device 16, an actual voltage applied to each power application terminal 35 is individually changed by the corresponding power application adjuster 50.

When the plating processing is performed, the actual voltage applied to each power application terminal 35 is adjusted by the corresponding power application adjuster 50 such that a relatively high voltage is applied to the division surface 13sm on the central side, whereas a relatively low voltage is applied to the division surface 13sm on the outer peripheral side. Accordingly, the plating processing is performed so as to reduce the influence of the voltage drop of the second electrode 13, so that the film thickness of the plating metal can be made uniform over the entire processing surface Ws.

In addition, the number of each of the power application terminals 35 and the power application adjusters 50 assigned to each division surface 13sm may be one or more.

Instead of employing the power application adjuster 50, the power applying device 16 may change the voltage (actual voltage) directly applied to each power application terminal 35. In this case as well, the plating processing can be performed so as to reduce the influence of the voltage drop of the substrate W, so that the film thickness of the plating metal deposited on the processing surface Ws can be made uniform.

### Another Modification Example

In the above-described examples, the second electrode 13 is positioned above the substrate W during the plating processing. However, the second electrode 13 may be positioned below the substrate W during the plating processing. In this case as well, while the plating processing is being performed, the processing surface Ws of the substrate W and the electrode facing surface 13s of the second electrode 13 face each other with the plating liquid Lp therebetween.

It should be noted that the exemplary embodiments and the modification examples described above are illustrative in all aspects and are not anyway limiting. The above-described exemplary embodiments and modification examples may be omitted, replaced and modified in various ways without departing from the scope and the spirit of claims. For example, the above-described exemplary embodiments and modification examples may be partially or entirely combined with each other, or an exemplary embodiment other than those described in the present disclosure may be partially or entirely combined with the above-described exemplary embodiments or modification examples.

Furthermore, a technical category for embodying the above-described technical concept is not particularly limited. By way of example, the above-described substrate liquid processing apparatus may be applied to another apparatus. Moreover, the above-described technical concept may be embodied by a computer-executable program for executing one or multiple sequences (processes) included in the above-described substrate liquid processing method on a computer. Further, the above-described technical concept may be embodied by a computer-readable non-transitory recording medium in which such a computer-executable program is stored.

1. A substrate liquid processing apparatus, comprising:
a substrate holder configured to hold a substrate rotatably;
a first electrode configured to be brought into contact with the substrate held by the substrate holder;
a second electrode having an electrode facing surface, the electrode facing surface being configured to be disposed at a position facing a processing surface of the substrate held by the substrate holder;
a seal member configured to surround the processing surface;
a plating liquid supply configured to supply a plating liquid onto the processing surface of the substrate held by the substrate holder;
a power applying device configured to apply a power to the processing surface of the substrate held by the substrate holder via the first electrode and the second electrode; and
a controller,
wherein the controller outputs a control signal to control the plating liquid supply and the power applying device to perform a first electrolytic plating processing by applying the power to the processing surface in a state that the plating liquid is in contact with a first facing range, which is a partial range of the electrode facing surface, and
the controller also outputs, after the first electrolytic plating processing is performed, a control signal to control the plating liquid supply and the power applying device to perform a second electrolytic plating processing by applying the power to the processing surface in a state that the plating liquid is in contact with a second facing range of the electrode facing surface, the second facing range being wider than the first facing range.

2. The substrate liquid processing apparatus of claim 1,
wherein the controller outputs a control signal such that a time when the power is applied to the processing surface in a state that the plating liquid is in contact with a range of the electrode facing surface narrower than a maximum electrode contact range, which is a maximum range of the electrode facing surface to be in contact with the plating liquid, is longer than a time when the power is applied to the processing surface in a state that the plating liquid is in contact with the maximum electrode contact range.

3. The substrate liquid processing apparatus of claim 2,
wherein the controller outputs a control signal to control the plating liquid supply such that the plating liquid is in contact with the entire maximum electrode contact range by taking five seconds or more after a supply of the plating liquid to the processing surface is started.

4. The substrate liquid processing apparatus of claim 1,
wherein the controller outputs a control signal to control the plating liquid supply and the power applying device such that a supply of the plating liquid to the processing surface is stopped in at least a part of a time during which the first electrolytic plating processing is being performed.

5. The substrate liquid processing apparatus of claim 1,
wherein a range of the electrode facing surface facing a central region of the processing surface of the substrate held by the substrate holder is protruded or recessed with respect to the processing surface.

6. The substrate liquid processing apparatus of claim 1,
wherein the plating liquid supply discharges the plating liquid toward a central region of the processing surface of the substrate held by the substrate holder.

7. The substrate liquid processing apparatus of claim 1,
wherein the plating liquid supply discharges the plating liquid toward an outer peripheral region of the processing surface of the substrate held by the substrate holder.

8. The substrate liquid processing apparatus of claim 1,
wherein the controller outputs a control signal to control the plating liquid supply and the power applying device to start a supply of the plating liquid to the processing surface after the power is applied to the processing surface.

9. The substrate liquid processing apparatus of claim 1,
wherein the electrode facing surface is divided into multiple division surfaces, and
the power applying device is configured to change the power applied to each of the multiple division surfaces individually between the multiple division surfaces under a control of the controller.

10. The substrate liquid processing apparatus of claim 1,
wherein the controller outputs a control signal such that the first electrolytic plating processing is performed in a state that the plating liquid is in contact with a maximum substrate contact range, which is a maximum range of the processing surface to be in contact with the plating liquid.

11. The substrate liquid processing apparatus of claim 1,
wherein the controller outputs a control signal such that the first electrolytic plating processing is performed in a state that the plating liquid is in contact with only a part of a maximum substrate contact range, which is a maximum range of the processing surface to be in contact with the plating liquid.

12. A substrate liquid processing method, comprising:
performing a first electrolytic plating processing by applying a power to a processing surface of a substrate held by a substrate holder via a first electrode and a second electrode in a state that the first electrode is in contact with the substrate and a plating liquid is in contact with a first facing range, which is a partial range of an electrode facing surface of the second electrode placed at a position facing the processing surface of the substrate; and
performing a second electrolytic plating processing by applying the power to the processing surface in a state that the plating liquid is in contact with a second facing range of the electrode facing surface, which is wider than the first facing range.
